(19) United States
(12) Patent Application Publication
(10) Pub. No.: US 2015/0290815 A1
(43) Pub. Date: Oct. 15, 2015

(54) PLANAR END EFFECTOR AND METHOD OF MAKING A PLANAR END EFFECTOR

(71) Applicant: Varian Semiconductor Equipment Associates, Inc., Gloucester, MA (US)

(72) Inventors: Paul E. Pergande, Austin, TX (US); Paul Forderhase, Austin, TX (US)

(73) Assignee: Varian Semiconductor Equipment Associates, Inc., Gloucester, MA (US)

(21) Appl. No.: 14/251,107

(22) Filed: Apr. 11, 2014

(51) Int. Cl. B25J 15/00; H01L 21/683; B32B 9/00; B32B 38/18; B32B 37/12; H01L 21/677; B32B 38/00

(52) U.S. Cl. CPC B25J 15/0014; H01L 21/67742; H01L 21/683; B32B 38/0004; B32B 38/1858; B32B 37/1284; B32B 9/007; B32B 2250/02; B32B 2457/14; B32B 2313/04

(57) ABSTRACT

A planar end effector and method of making a planar end effector. The method may include the steps of applying adhesive to a first side of a first sheet, the first sheet having a second side opposite the first side, and disposing a first side of a second sheet on the adhesive, the second sheet having a second side opposite the first side, wherein the first sides of the first and second sheets confront each other and define an at least partially adhesive-filled bond-gap therebetween and wherein the second sides of the first and second sheets are parallel with one another. The method may further include the steps of curing the adhesive to produce a planar composite workpiece including the first sheet, the second sheet, and an intermediate adhesive layer, and cutting the end effector from the composite workpiece.

### FIELD OF THE DISCLOSURE

Embodiments of the present disclosure generally relate to the field of substrate processing, and more particularly to a planar robotic end effector and a method of making thereof.

### BACKGROUND OF THE DISCLOSURE

Silicon wafers are used in the fabrication of semiconductors and solar cells. During such fabrication, the wafers are subjected to a multi-step manufacturing process that may involve a plurality of machines and a plurality of stations. Thus, the wafers need to be transported from one machine/station to another machine/station one or more times.

The transport of the wafers typically employs apparatuses called end effectors. A typical end effector may be a flat platform having a hand-like or claw-like appearance defined by a base unit with a plurality of flat fingers or tines extending therefrom. The fingers may be adapted to support a wafer in a horizontal orientation. During operation, the end effector may typically be moved linearly (e.g., forward and backward) as well as rotationally all in the same plane (e.g., x-y axis). The end effector may also be moved in a third direction along a z-axis to provide a full range of motion.

It is generally desirable for end effectors to be formed of materials that are lightweight, stiff, and that do not produce contaminants (i.e., particulate matter) during use. It is also generally desirable for end effectors to have working surfaces (i.e., surfaces that engage wafers) that are very flat, hard, and easy to clean.

Carbon fiber composite (CFC) is a stiff, lightweight material that is widely used in the construction of high-performance structures such as racing bicycles, automobiles, aircraft, spacecraft, boats, and robots. A well-known method for producing such structures from CFC employs a technique that is commonly referred to as “vacuum bagging,” in which a mixture of fiber reinforcement and adhesive matrix is pressed against a mold half by a membrane, wherein the membrane is drawn against the exposed (non-mold) side of the fiber/adhesive composite by a vacuum that is introduced therebetween. Since a permeable breather is commonly used to distribute the vacuum across the exposed side of the composite, the vacuum bagging process yields a part with a smooth side, commonly referred to as the “tool side,” and an opposing rough side, commonly referred to as the “bag side.” An end effector produced using the vacuum bagging process is generally unsuitable for use in substrate handling since the rough, bag side of the part cannot be effectively cleaned or sealed.

Closed molds can be employed to make CFC end effectors having suitably smooth top and bottom surfaces, but such molds are extremely expensive and require a great deal of lead-time to produce. Closed molds therefore tend to constrain the design and improvement of end effectors, since the substantial investment needed to produce a closed mold tool discourages design changes and innovation that would affect the footprint of an end effector already in production.

In view of the foregoing, it would be advantageous to provide a method for producing an end effector formed of CFC, wherein the method requires a negligible investment in tooling, is amenable to design changes, and yields a part having ultra-flat, non-contaminating surfaces that can be easily cleaned.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In general, various embodiments of the present disclosure provide a method and an apparatus for making a planar end effector. A first exemplary embodiment of a method in accordance with the present disclosure may include the steps of applying adhesive to a first side of a first sheet, the first sheet having a second side opposite the first side, and disposing a first side of a second sheet on the adhesive, the second sheet having a second side opposite the first side, wherein the first sides of the first and second sheets confront each other and define an at least partially adhesive-filled bond-gap therebetween and wherein the second sides of the first and second sheets are parallel with one another. The method may further include the steps of curing the adhesive to produce a planar composite workpiece including the first sheet, the second sheet, and an intermediate adhesive layer, and cutting the end effector from the composite workpiece.

An exemplary embodiment of a planar end effector produced using the methods of the present disclosure may include a first sheet having a first side that is rough and having a second side opposite the first side that is relatively smooth compared to the first side, a second sheet having a first side that is rough and having a second side opposite the first side that is relatively smooth compared to the first side, and an adhesive layer disposed intermediate and bonded to the first side of the first sheet and the first side of the second sheet, wherein the second side of the first sheet and the second side of the second sheet are parallel with one another.

An apparatus for making a planar end effector in accordance with the present disclosure may include a vacuum jig having a top mold half formed of an inner plate and an outer plate secured together in a stacked relationship, the inner plate having a raised portion with a flat engagement surface, the engagement surface having a plurality of perforations adapted to be connected to a vacuum source for creating a vacuum at the engagement surface, and a bottom mold half formed of an inner plate and an outer plate secured together in a stacked relationship, the inner plate having a raised portion with a flat engagement surface, the engagement surface having a plurality of perforations adapted to be connected to a vacuum source for creating a vacuum at the engagement surface.

### BRIEF DESCRIPTION OF THE DRAWINGS

By way of example, various embodiments of the disclosed device will now be described, with reference to the accompanying drawings, in which:

FIG. 1a is cut-away view illustrating an exemplary embodiment of a vacuum jig in accordance with the present disclosure;

FIG. 1b is a detail view of a portion the exemplary vacuum jig of FIG. 1;

FIG. 2 is a flow diagram illustrating an exemplary method in accordance with the present disclosure;

FIGS. 3a-3g are a sequence of views illustrating the steps of the method set forth in the FIG. 2.

### DETAILED DESCRIPTION

A method and apparatus for making a planar end effector having ultra-flat, non-contaminating surfaces in accordance with the present disclosure will now be described more fully hereinafter with reference to the accompanying drawings, in which preferred embodiments of the method and apparatus are shown. The method and apparatus, however, may be embodied in many different forms and should not be construed as being limited to the embodiments set forth herein. Rather, these embodiments are provided so that this disclosure will be thorough and complete, and will fully convey the scope of the method and apparatus to those skilled in the art. In the drawings, like numbers refer to like elements throughout unless otherwise noted.

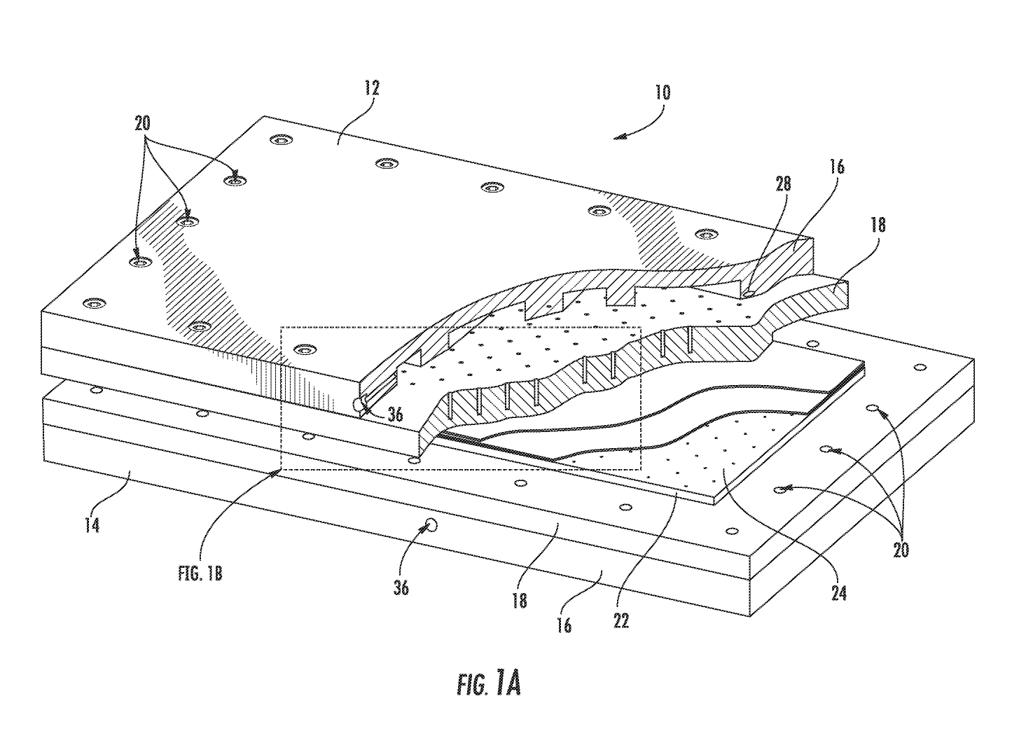

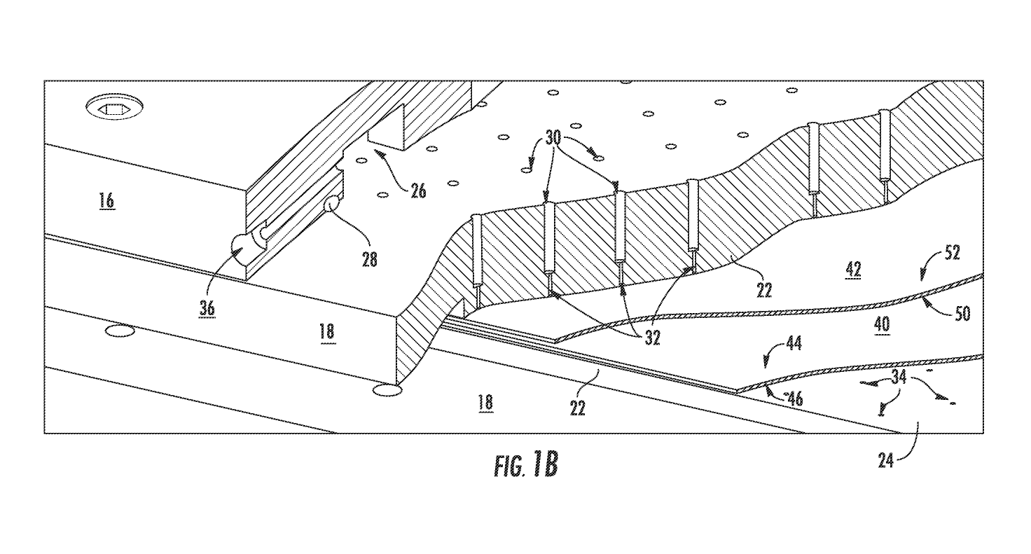

FIGS. 1a and 1b respectively illustrate a cut-away view and a detail view of an exemplary vacuum jig 10 (hereinafter “the jig 10”) in accordance with an embodiment of the present disclosure. The jig 10 may be used to effectuate a method for making ultra-flat, planar end effectors as further described below. For the sake of convenience and clarity, terms such as “top,” “bottom,” “upper,” “lower,” “vertical,” “horizontal,” “lateral,” “longitudinal,” “inner,” and “outer” will be used herein to describe the relative placement and orientation of the features and components of the jig 10, each with respect to the geometry and orientation of the jig 10 as it appears in FIG. 1a. Said terminology will include the words specifically mentioned, derivatives thereof, and words of similar import.

The jig 10 may include substantially identical top and bottom mold halves 12, 14. It will be understood that while certain features and components of the mold half 12 and certain other features and components of the mold half 14 are not within view in the drawings, the mold halves 12, 14 include substantially identical features and components, and that such features and components will be referred to with like numbers in the following description and in the drawings. For example, if the mold half 12 is shown and described as having a plenum 26, it will be understood that the mold half 14 has a substantially identical plenum 26, even if that feature of the mold half 14 is not within view in the drawings.

Each mold half 12, 14 of the jig 10 may include outer and inner plates 16, 18 that may be fastened together in a flatly-abutting, stacked relationship, such as with mechanical fasteners (e.g., bolts) that may extend through vertically-aligned pairs of fastener holes 20 formed in the outer and inner plates 16, 18. Alternatively, it is contemplated that each mold half 12, 14 may be formed as a unitary, contiguous body. The inner plate 18 may have a raised portion 22 having a flat engagement surface 24. An inner face of the outer pate 16 may define a plenum 26 that includes a plurality of interconnected chambers. The plenum 26 may be sealed by an O-ring 28 disposed between the outer and inner plates 16, 18 and that surrounds the plenum 26. The plenum 26 may be in fluid communication with a plurality of vertically-extending holes 30 formed through the inner plate 18, wherein each hole 30 is in-turn in fluid communication with a vertically-extending hole 32 formed through the raised portion 22. The holes 32 in the raised portion may have a smaller diameter than the holes 30 in the inner plate 18, but this is not critical. The holes 32 may thus define corresponding perforations 34 in the engagement surface 24 of the raised portion 22. The holes 32 and perforations 34 may be evenly distributed throughout the entire raised portion 22 and engagement surface 24, respectively.

Each mold half 12, 14 may further include a vacuum port 36 that may be formed through a sidewall of the outer plate 16 and that may be in fluid communication with the plenum 26. By coupling a vacuum source (not shown) to the vacuum port 36, air may be evacuated through the plenum 26 and holes 30, 32, creating a vacuum between the mold halves 12, 14. This vacuum may be maintained in the plenum 26, the holes 30, 32 and at the engagement surface 24, by virtue of the O-ring 28, which prevents air from the external environment from entering the plenum 26. The jig 10 may therefore by used to firmly hold workpieces, such as first and second sheets 40, 42 of carbon fiber composite (CFC), flatly against the engagement surfaces 24 of the mold halves 12, 14. By holding the first and second sheets 40, 42 of CFC against the engagement surface 24 of each of the mold halves 12, 14, the outer surfaces of the first and second sheets 40, 42 can be maintained with a high degree of parallelism and planarity within the jig 10. As will be described in greater detail below, maintaining the first and second sheets 40, 42 in this manner, while introducing an adhesive between the first and second sheets and allowing that adhesive to cure, results in an end effector having the same degree of parallelism and planarity as the engagement surfaces 24 of the mold halves 12, 14. The specific utility of the jig 10 will become apparent in the context of the method of the present disclosure described below.

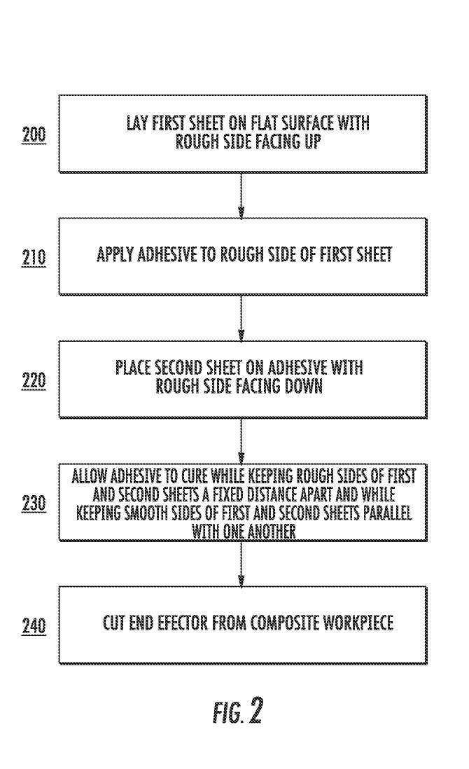

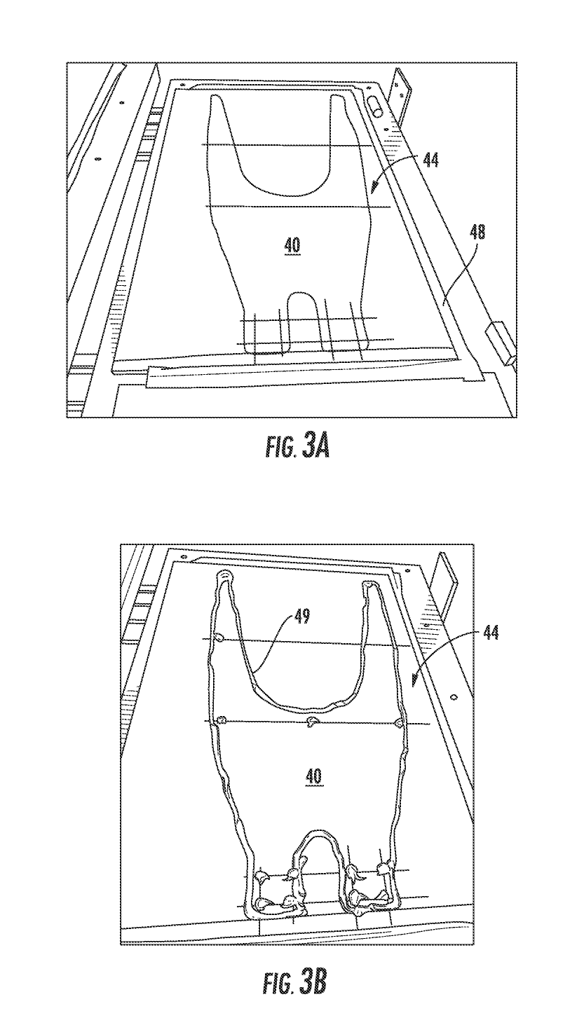

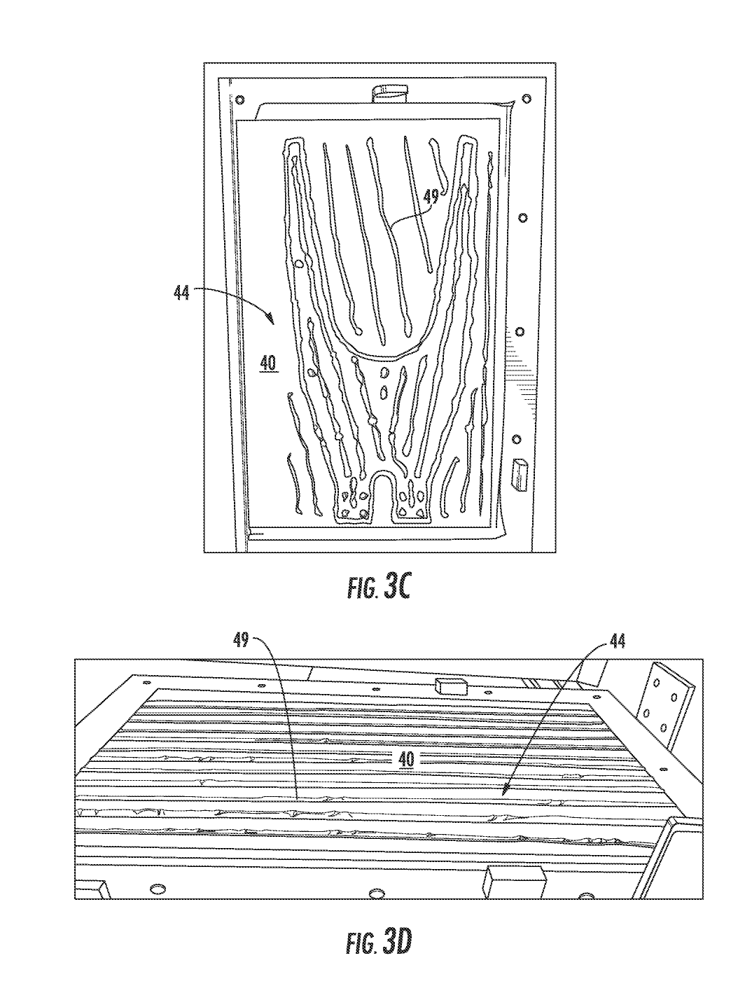

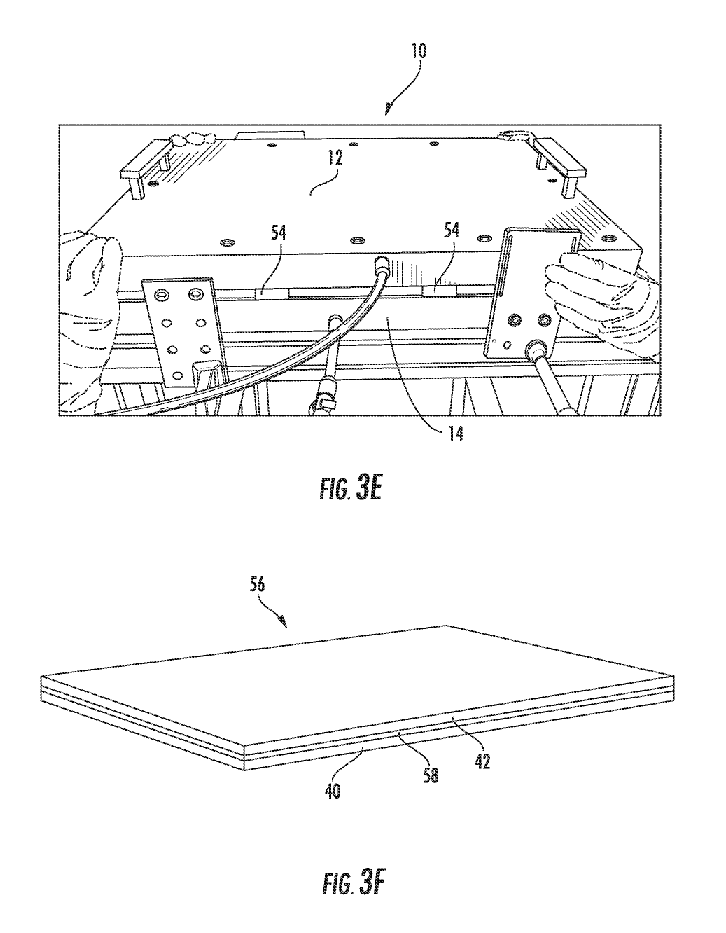

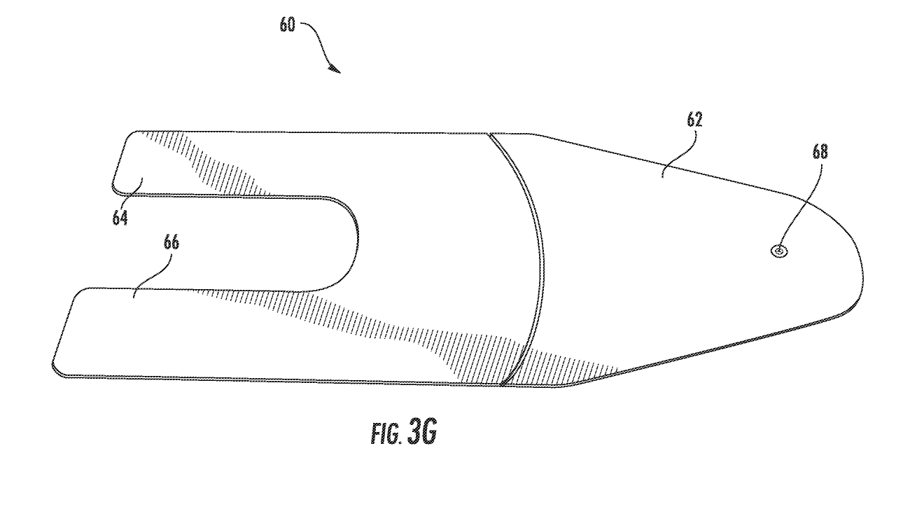

Referring to FIG. 2, a flow diagram illustrating an exemplary method for making an ultra-flat, planar end effector formed of carbon fiber composite (CFC) in accordance with the present disclosure is shown. The method will now be described in detail in conjunction with the jig 10 shown in FIGS. 1a and 1b and the manufacturing steps depicted in FIGS. 3a-3g.

At a first step 200, a substantially planar, rectangular first sheet 40 of CFC may be laid on a flat surface as shown in FIG. 3a. In one embodiment of the method, the flat surface may be the engagement surface 24 of the mold half 14 of the jig 10 (shown in FIGS. 1a and 1b). In other embodiments, the flat surface may be a table top, floor, or other flat work surface. The first sheet 40 may be produced using a “vacuum-bagging” technique that may provide the first sheet 40 with a first side 44 which, in some embodiments, may be relatively rough, and an opposing second side 46 (shown in FIGS. 1a and 1b) which, in some embodiments, may be relatively smooth or flat compared to the first side 44. The term “rough” is defined herein to mean one or more of uneven, irregular, not smooth, not flat, textured, pitted, etc. In other embodiments of the method, the first sheet 40 may be produced using processes which provide the first sheet 40 with first and second sides 44, 46 that are both smooth.

The first sheet 40 may be disposed on the above-described flat surface with the second side 46 facing down and the first side 44 facing up. The first sheet 40 may optionally be temporarily secured to the flat surface in a desired orientation, such as with tape 48 (as shown in FIG. 3a) and/or other fasteners or adhesives which, if using the vacuum jig 10, may seal the first sheet 40 to the engagement surface 24 so that a vacuum can effectively be established therebetween. If a vacuum jig is not used, the first sheet 40 may be flatly secured to a flat surface using a temporary, secondary adhesive, such as any low-strength bonding agent, including, but not limited to, fugitive adhesive or pressure sensitive adhesive. Alternatively, it is contemplated that the first sheet 40 may be flatly secured to a flat surface using a film that is treated with a low-tack, pressure sensitive adhesive. Still further, it is contemplated that the first sheet 40 may be flatly secured to a flat surface using a primary adhesive of a reactive nature, such as a high-density, high-strength polyurethane foam consisting of two precursors. During curing, these precursors may react and increase in volume, thereby forcibly “sandwiching” the flatly-abutting first and second sheets 40, 42 (described below) together and keeping them flat while they are bonded together as further described below.

At step 210 of the exemplary method, an amount of adhesive 49 may be applied to the first side 44 of the first sheet 40 as shown in FIGS. 3b-d. The adhesive 49 may be any appropriate adhesive, a non-limiting example of which is a flow-modified epoxy. In one embodiment, the adhesive 49 may be applied to the first sheet 40 in a manner that outlines and covers the edges and other features (e.g., mounting holes) of a desired end effector design as shown in FIG. 3b. The other portions of the first side 44 may then be covered with the adhesive 49 in an evenly-distributed manner as shown in FIG. 3c. By outlining and covering the edges and mounting holes of the desired end effector design with the adhesive 49, it is ensured that when the second sheet 42 is adhered to the first sheet 40 and an end effector is subsequently cut and drilled from the adhered first and second sheets 40, 42 (as described below), the cut lines and drill holes will pass entirely through cured adhesive 49, thereby ensuring that the edges of the resulting end effector, including the edges of the mounting holes drilled therethrough, are free of pores that could otherwise result from uneven or incomplete distribution of adhesive at the edges. Alternatively, in another embodiment of the exemplary method, it is contemplated that the adhesive 49 may be applied to the first side 44 of the first sheet 40 without regard to the outline and other features of the desired end effector design as shown in FIG. 3d.

At step 220, a planar, rectangular second sheet 42 of CFC may be flatly placed on top of the adhesive-covered first side 44 of the first sheet 40. The second sheet 42 may be substantially similar to the first sheet 40, and may be similarly produced using a vacuum-bagging technique that provides the second sheet 42 with a first side 50 which, in some embodiments, may be relatively rough, and an opposing second side 52 (shown in FIGS. 1a and 1b) which, in some embodiments, may be relatively smooth or flat compared to the first side 50. The second sheet 42 may be placed on top of the adhesive-covered first sheet 40 with the first side 50 facing down and the smooth side 52 facing up. The first sides 44, 50 of the first and second sheets 40, 42 are thereby disposed in a confronting relationship and are separated by the adhesive 49. In one embodiment of the method, the first and second sheets 40, 42 may be stacked and adhered in the above-described manner using the jig 10 shown in FIGS. 1a and 1b. Particularly, the second side 46 of the first sheet 40 may be vacuum sealed flatly against the flat engagement surface 24 of the bottom mold half 14 and the smooth side 52 of the second sheet 42 may be vacuum sealed flatly against the flat engagement surface 24 of the top mold half 12. The top mold half 12 may then be inverted and lowered onto the bottom mold half 14 with the first side 50 of the second sheet 42 flatly placed on top of the adhesive-covered first side 44 of the first sheet 40 as shown in FIGS. 1a, 1b, and 3e.

At step 230, the adhesive 49 between the first and second sheets 40, 42 may be allowed to cure while the first sides 44, 50 of the first and second sheets 40, 42 are held a short, fixed distance apart from one another, forming a so-called “bond-gap” therebetween that is mostly filled with adhesive, and with the second sides 46, 52 of the first and second sheets 40, 42 held in a substantially parallel relationship with one another. In one embodiment, the first and second sheets 40, 42 may be held in this manner using the above-described jig 10. For example, with the first and second sheets 40, 42 vacuum sealed to the engagement surfaces 24 of the jig 10 and the mold halves 12, 14 stacked so that the first sides 44, 50 of the first and second sheets 40, 42 are disposed in a confronting relationship as described in step 220 above, one or more spacers or “gap blocks” 54 of substantially identical height may be interposed between the top and bottom mold halves 12, 14 as shown in FIG. 3e. Such gap blocks 54 may be positioned inward of the lateral and longitudinal edges of the inner plates 16, 18 and outward of the raised portions 22 of the inner plates 16, 18 (i.e., vertically intermediate the non-raised portions of the inner plates 16, 18). The gap blocks 54 may have a height that maintains the mold halves 12, 14 a specified, uniform distance apart so that the resulting end effector has a desired predetermined thickness.

The process described in steps 200-230 of the exemplary method may yield a composite workpiece 56, shown in FIG. 3f, that includes a substantially uniform, cured adhesive layer 58 sandwiched between the first and second sheets 40, 42. Since the second sides 46, 52 of the first and second sheets 40, 42 were held in a parallel relationship and the first sides 44, 50 were held apart from one another during curing of the adhesive layer 58, the composite workpiece 56 may be highly planar (i.e., having parallel top and bottom surfaces), with any surface irregularities of the first sides 44, 50 having been “absorbed” by the adhesive layer 58 during curing. That is, the surface irregularities of the confronting first sides 44, 50 may not affect the planarity of the composite workpiece 56 as they otherwise might if the first sides 44, 50 were placed in direct contact with one another (i.e., with no bond-gap therebetween), with their respective surface irregularities engaging each other.

At step 240, the composite workpiece 56 can be cut and drilled to yield a completed end effector 60 as shown in FIG. 3g. The end effector 60 is shown as having a base portion 62 with two fingers 64, 66 extending therefrom, and a wrist portion 68 though it will be appreciated that many other end effector designs may be cut, drilled, or otherwise formed from the composite workpiece 56 without departing from the present disclosure. For example, alternative end effector designs may have one finger or may have more than two fingers. Alternative end effector designs may also include various holes, slots, notches, and/or other features formed in the base portion 62, such as may be provided for facilitating connection to a robot or other device.

Owing to the high-planarity of the composite workpiece 56 described above, the completed end effector 60 may also be highly planar. Moreover, since the top and bottom sides of the end effector 60 are formed of the smooth sides 44, 50 of the first and second sheets 40, 42, respectively, the surfaces of the end effector 60 may be smooth and ultra-flat (e.g. less than about 0.005 inches of variation over about 24 inches of surface). Thus, the end effector 60 may be very light, very stiff, easy to clean, and is not prone to generating, trapping, or distributing contaminants (i.e., particulate matter) during substrate handling processes. Still further, implementing new end effector designs using the above-described method requires little additional investment, since all that is required is to cut the new design from a new composite workpiece that may be produced using the same processes and equipment used in producing composite workpieces for prior end effector designs.

As used herein, an element or step recited in the singular and proceeded with the word “a” or “an” should be understood as not excluding plural elements or steps, unless such exclusion is explicitly recited. Furthermore, references to “one embodiment” of the present disclosure are not intended to be interpreted as excluding the existence of additional embodiments that also incorporate the recited features.

The present disclosure is not to be limited in scope by the specific embodiments described herein. Indeed, various other embodiments of and modifications to the present disclosure, in addition to those described herein, will be apparent to those of ordinary skill in the art from the foregoing description and accompanying drawings. These other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A method of making an end effector, the method comprising:
applying adhesive to a first side of a first sheet, the first sheet having a second side opposite the first side;
disposing a first side of a second sheet on the adhesive, the second sheet having a second side opposite the first side, wherein the first sides of the first and second sheets confront each other and define an at least partially adhesive-filled bond-gap therebetween and wherein the second sides of the first and second sheets are parallel with one another;
curing the adhesive to produce a planar composite workpiece including the first sheet, the second sheet, and an intermediate adhesive layer; and
cutting the end effector from the composite workpiece.

2. The method of claim 1, wherein the second sides of the first and second sheets are flatter than the first sides of the first and second sheets.

3. The method of claim 1, further comprising vacuum sealing the second side of the first sheet to a bottom mold half of a vacuum jig and vacuum sealing the second side of the second sheet to a top mold half of the vacuum jig.

4. The method of claim 3, wherein disposing the first side of the second sheet on the adhesive comprises stacking the top mold half of the vacuum jig on the bottom mold half of the vacuum jig with the first sides of the first and second sheets disposed in a confronting relationship.

5. The method of claim 4, further comprising interposing a gap block between the top mold half and the bottom mold half to hold the top mold half and the bottom mold half a fixed, uniform distance apart from one another, thereby creating the bond-gap between the first sides of the first and second sheets and disposing the second sides of the first and second sheets in a parallel relationship with one another.

6. The method of claim 5, wherein interposing the gap block between the top mold half and the bottom mold half comprises placing the gap block between an edge of the first sheet and an edge of the bottom mold half and between an edge of the second sheet and an edge of the top mold half.

7. The method of claim 1, wherein applying adhesive to a first side of the first sheet comprises depositing the adhesive on the first side of the first sheet in a manner that outlines an end effector design.

8. The method of claim 1, further comprising making the first sheet from carbon fiber composite using a vacuum bagging technique to produce the second side and the first side of the first sheet.

9. The method of claim 1, further comprising making the second sheet from carbon fiber composite using a vacuum bagging technique to produce the second side and the first side of the second sheet.

10. A planar end effector comprising:
a first sheet having a first side that is and a second side opposite the first side;
a second sheet having a first side and a second side opposite the first side; and
an adhesive layer disposed intermediate and bonded to the first side of the first sheet and the first side of the second sheet;
wherein the second side of the first sheet and the second side of the second sheet are parallel with one another.

11. The planar end effector of claim 10, wherein the first sheet is formed of carbon fiber composite.

12. The planar end effector of claim 10, wherein the second sheet is formed of carbon fiber composite.

13. The planar end effector of claim 10, wherein the adhesive layer is formed of a flow-modified epoxy.

14. The planar end effector of claim 10, wherein the second side of the first sheet and the second side of the second sheet each have a flatness of less than 0.005 inches of variation over 24 inches of surface.

15. The planar end effector of claim 10, wherein the adhesive layer forms a continuous, non-porous edge intermediate and parallel with an edge of the first sheet and an edge of the second sheet.

16. A vacuum jig for making a planar end effector, the vacuum jig comprising a top mold half formed of an inner plate and an outer plate secured together in a stacked relationship, the inner plate having a raised portion with a flat engagement surface, the engagement surface having a plurality of perforations adapted to be connected to a vacuum source for creating a vacuum at the engagement surface.

17. The vacuum jig of claim 16, wherein the inner plate and the outer plate define a plenum therebetween, and wherein the inner plate has a plurality of holes formed therethrough, each hole being in fluid communication with the plenum and with one of the perforations in the engagement surface.

18. The vacuum jig of claim 17, further comprising a vacuum port formed in the outer plate and in fluid communication with the plenum for providing a connection to the vacuum source.

19. The vacuum jig of claim 17, further comprising an O-ring gland interposed between the inner plate and outer plate and surrounding the plenum for sealing the plenum from an external environment.

20. The vacuum jig of claim 16, further comprising a bottom mold half formed of an inner plate and an outer plate secured together in a stacked relationship, the inner plate having a raised portion with a flat engagement surface, the engagement surface having a plurality of perforations adapted to be connected to a vacuum source for creating a vacuum at the engagement surface.
